(19) United States
(12) Patent Application Publication
(10) Pub. No.: US 2018/0213656 A1
(43) Pub. Date: Jul. 26, 2018

(54) DECOMPRESSION CONTAINER, PROCESSING APPARATUS, PROCESSING SYSTEM, AND METHOD OF PRODUCING FLAT PANEL DISPLAY

(71) Applicants: CANON KABUSHIKI KAISHA, Tokyo (JP); CANON TOKKI CORPORATION, Mitsuke-shi (JP)

(72) Inventors: Jumpei Mori, Inagi-shi (JP); Akira Ohta, Nagaoka-shi (JP)

(21) Appl. No.: 15/872,269

(22) Filed: Jan. 16, 2018

(30) Foreign Application Priority Data
Jan. 20, 2017 (JP) 2017-009001

(51) Int. Cl. H05K 5/00; H05K 5/06

(52) U.S. Cl. CPC H05K 5/0017; H05K 5/068

(57) ABSTRACT

A decompression container includes an outer wall including a first member. The first member includes a first base portion and a first rib portion. The first base portion includes a first surface having a quadrilateral shape. The first rib portion being disposed on the first surface. The first rib portion includes a first rib surrounding a center of the first surface, a plurality of second ribs connected to the first rib and extending toward sides of the quadrilateral shape of the first surface, and a plurality of third ribs that are respectively disposed to oppose respective corners of the quadrilateral shape of the first surface, extend toward respective pairs of sides forming the respective corners of the quadrilateral shape of the first surface, and are apart from one another.

### BACKGROUND OF THE INVENTION

### Field of the Invention

The present invention relates to a decompression container that is decompressed inside, a processing apparatus including the decompression container, a processing system including the processing apparatus, and a method of producing a flat panel display using the decompression container.

### Description of the Related Art

For example, in a processing apparatus such as a film forming apparatus that is used for producing a semiconductor device or a flat panel display: FPD, processes such as a film forming process is performed in a decompression container. In a decompression container of this type, the inside of the container is decompressed and thus a pressure is applied to the wall of the container. At this time, if the strength of the wall of the container is low, the wall will be deformed, and thus there will arise a problem such as air getting into the container through a joined portion or the like and thus the pressure inside the container failing to be maintained, or the deformation of the wall interfering with contained objects disposed in the container. Therefore, the decompression container needs to have strength against the pressure. In addition, since the applied pressure becomes higher as the size of the container becomes larger, the strength of the container needs to be increased when increasing the size of the container. Therefore, a larger decompression container becomes heavier. For example, in a processing apparatus such as a film forming apparatus used for producing a semiconductor device or an FPD, since the size of a decompression container increases in accordance with the increase of the size of a wafer or a glass substrate, the weight of the decompression container also tends to increase. This means that the costs for the material of the decompression and the costs for flooring for installing the decompression container increase. Therefore, it is desired that a decompression container as light as possible while having sufficient strength to bear the pressure is provided.

As a means for reinforcing a decompression container, for example, Japanese Patent Laid-Open No. 2010-243015 proposes a rib structure. By providing ribs standing on a wall surface to be subjected to the pressure, a decompression container stronger and lighter than a decompression container having a simple planar structure can be obtained.

However, although the rib structure of Japanese Patent Laid-Open No. 2010-243015 can realize a decompression container stronger and lighter than a decompression container not provided with a rib, further reduction of weight has been desired for a decompression container used in a processing apparatus or the like.

### SUMMARY OF THE INVENTION

According to a first aspect of the present invention, a decompression container includes an outer wall including a first member, the first member including a first base portion and a first rib portion, the first base portion including a first surface having a quadrilateral shape, the first rib portion being disposed on the first surface. The first rib portion includes a first rib surrounding a center of the first surface, a plurality of second ribs connected to the first rib and extending toward sides of the quadrilateral shape of the first surface, and a plurality of third ribs that are respectively disposed to oppose respective corners of the quadrilateral shape of the first surface, extend toward respective pairs of sides forming the respective corners of the quadrilateral shape of the first surface, and are apart from one another.

According to a second aspect of the present invention, a method of producing a flat panel display includes disposing a substrate inside a decompression container comprising an outer wall, the outer wall comprising a member, the member comprising a base portion and a rib portion, the base portion comprising a surface having a quadrilateral shape, the rib portion being disposed on the surface, the rib portion comprising a first rib, a plurality of second ribs, and a plurality of third ribs, the first rib surrounding a center of the surface, the plurality of second ribs being connected to the first rib and extending toward sides of the quadrilateral shape of the surface, the plurality of third ribs being respectively disposed to oppose respective corners of the quadrilateral shape of the surface, extending toward respective pairs of sides forming the respective corners of the quadrilateral shape of the surface, and being apart from one another, forming a film of a material of the flat panel display on the substrate in the decompression container, and taking out the substrate from the decompression container.

Further features of the present invention will become apparent from the following description of exemplary embodiments with reference to the attached drawings.

### BRIEF DESCRIPTION OF THE DRAWINGS

FIG. 1 is an explanatory diagram illustrating a processing system according to a first exemplary embodiment.

FIG. 2 is an explanatory diagram illustrating a processing apparatus according to the first exemplary embodiment.

FIG. 3 is a perspective view of a decompression container according to the first exemplary embodiment.

FIG. 4A is a plan view of an upper surface portion or a lower surface portion of the decompression container according to the first exemplary embodiment.

FIG. 4B is a plan view of a side surface portion of the decompression container according to the first exemplary embodiment.

FIG. 5 is a perspective view of a decompression container according to a second exemplary embodiment.

FIG. 6 is a plan view of a door of the decompression container according to the second exemplary embodiment.

FIG. 7A is an explanatory diagram of dimensions of a member constituting the upper surface portion and the lower surface portion of the decompression container of the first exemplary embodiment.

FIG. 7B is an explanatory diagram of dimensions of a member constituting the side surface portion of the decompression container of the first exemplary embodiment.

FIG. 8 is a perspective view of a decompression container of Comparative Example 1.

FIG. 9 is an explanatory diagram of dimensions of a door of Examples 2 and 3.

FIG. 10 is an explanatory diagram of dimensions of a door of a decompression container of Comparative Example 2.

FIGS. 11A to 11E are explanatory diagrams of modification examples of a first rib.

FIGS. 12A to 12E are explanatory diagrams of modification examples of second ribs.

FIGS. 13A and 13B are explanatory diagrams of modification examples of third ribs.

FIG. 14 is a perspective view of a modification example of the decompression container according to the second exemplary embodiment.

### DESCRIPTION OF THE EMBODIMENTS

Hereinafter, exemplary embodiments of the present invention will be described in detail with reference to drawings.

### First Exemplary Embodiment

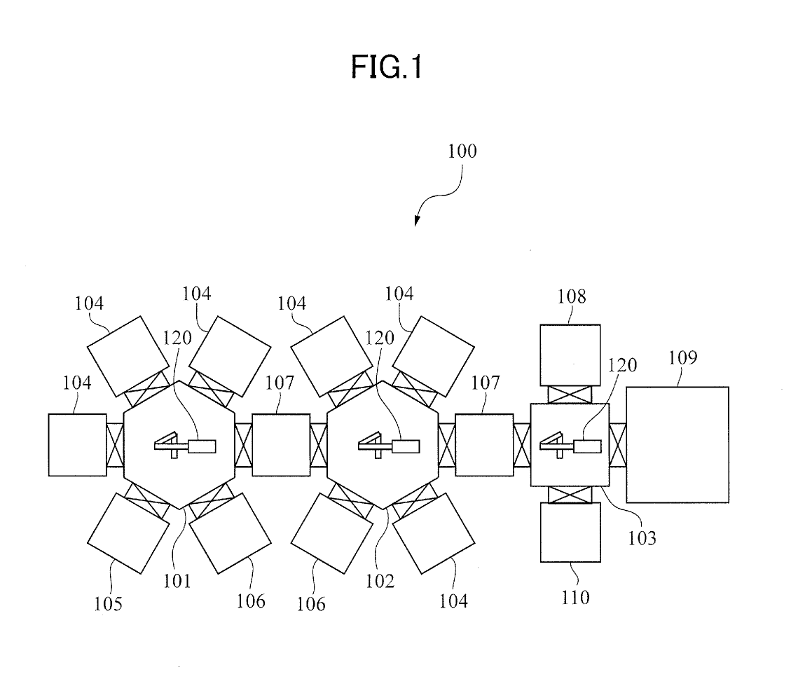

FIG. 1 is an explanatory diagram illustrating a processing system according to a first exemplary embodiment. A processing system 100 is a system for producing a flat panel display. Examples of the fiat panel display include an organic electroluminescence display: OLED display, a liquid crystal display, a plasma display, a field emission display, and electronic paper, and a case where the flat panel display is an OLED display will be described in the first exemplary embodiment.

The processing system 100 includes decompression containers 101 to 110 that are vacuum chambers. The decompression containers 101, 102, and 103 are conveyance chambers in which a substrate serving as a workpiece is conveyed by robots 120 disposed therein and serving as conveyance mechanisms. The decompression containers 101 and 102 are interconnected via a decompression container 107, and the decompression containers 102 and 103 are interconnected via another decompression container 107. The decompression containers 107 are passing chambers in which the substrate is passed over.

A plurality of decompression containers 104, a decompression container 105, and a decompression container 106 are connected to the decompression container 101. A plurality of decompression containers 104 and a decompression container 106 are connected to the decompression container 102. A decompression container 108, a decompression container 109, and a decompression container 110 are connected to the decompression container 103.

The decompression containers 104 are deposition chambers in which a thin film of a material such as a metal material or an organic material is deposited on a substrate supported on a tray. The decompression container 105 is a substrate supply chamber through which a substrate is supplied from the outside. The decompression containers 106 are accommodation chambers in which trays for supporting the substrate are accommodated, and a tray is conveyed thereto each time a film of a predetermined thickness or a thicker film is deposited on a tray in a decompression container 104. By taking out a tray conveyed to a decompression container 106, the tray can be cleaned.

The decompression container 108 is a glass supply chamber through which sealing glass is supplied, and the decompression container 109 is a sticking chamber in which the sealing glass is stuck on the substrate on which a film has been formed. The decompression container 110 is a taking-out chamber through which a produced OLED display is taken out.

A method of producing an OLED display will be described. A substrate supplied to the decompression container 105 is sequentially conveyed to the respective decompression containers 104 by the robot 120 in the decompression container 101, and is subjected to film forming processes. After film formation is completed by vapor deposition apparatuses disposed in the respective decompression containers 104, the substrate is conveyed to a decompression container 107, and thus the substrate is passed over to the robot 120 in the decompression container 102. Then, the substrate is sequentially conveyed to the respective decompression containers 104 by the robot 120 in the decompression container 102, and is subjected to film forming processes. After film formation is completed in the respective decompression containers 104, the substrate is conveyed through a decompression container 107 serving as a conveyance path to be passed over to the robot 120 in the decompression container 103, and is conveyed to the decompression container 109. Sealing glass supplied to the decompression container 108 is conveyed to the decompression container 109 by the robot 120, the substrate and the sealing glass are stack together, and thus the OLED display is produced. The produced OLED display is conveyed to the decompression container 110 by the robot 120, and is thus taken out.

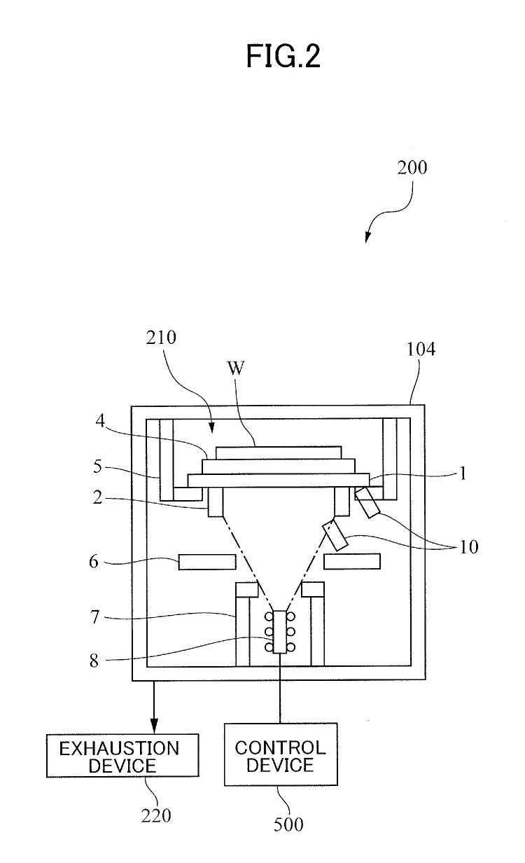

FIG. 2 is an explanatory diagram illustrating a processing apparatus 200 according to the first exemplary embodiment. The processing apparatus 200 illustrated in FIG. 2 is a film forming apparatus that forms a film on a substrate W serving as a workpiece by deposition, and includes a decompression container 104 illustrated in FIG. 1. The processing system 100 illustrated in FIG. 1 includes a plurality of processing apparatuses 200 illustrated in FIG. 2. The processing apparatuses 200 in the processing system 100 are each used in a part of production steps of the OLED display, that is, in a film forming step, and are each configured to deposit, for example, an organic material, on the substrate W serving as a workpiece disposed in the decompression container 104. The organic material to be deposited on the substrate W is a material to constitute an organic electroluminescence layer, and is, for example, Alq3 to constitute a light emitting layer.

A processing portion 210 is disposed in the decompression container 104. The processing portion 210 is a processing portion configured to perform a process on the substrate W serving as a workpiece disposed in the decompression container 104, and includes a deposition source 8. A tray 1 that supports the substrate W is disposed to oppose the deposition source 8. A deposition preventing member 2 is disposed on the deposition source side of the tray 1. A mask 4 is set on the tray 1. The substrate W is conveyed to the decompression container 104 by the robot 120 illustrated In FIG. 1, and alignment between the substrate W and the mask 4 is performed. The tray 1 and the substrate W are placed on a support portion 5. A reflector 7 is disposed to surround the deposition source 8. A shutter 6 is disposed above the deposition source 8. A deposition rate monitor 10 is disposed above the shutter 6. The deposition rate monitor 10 is used for measuring a deposition rate from the deposition source 8, and transmits a result of the measurement to a control device 500.

The control device 500 is configured to control film formation, and opens the shutter 6 and starts film formation on the substrate W when a monitored value of the deposition rate monitor 10 becomes stable at a desired value. The decompression container 104 is connected to an exhaustion device 220 such as a pump, and the inside of the decompression container 104 can be decompressed by causing the exhaustion device 220 to operate.

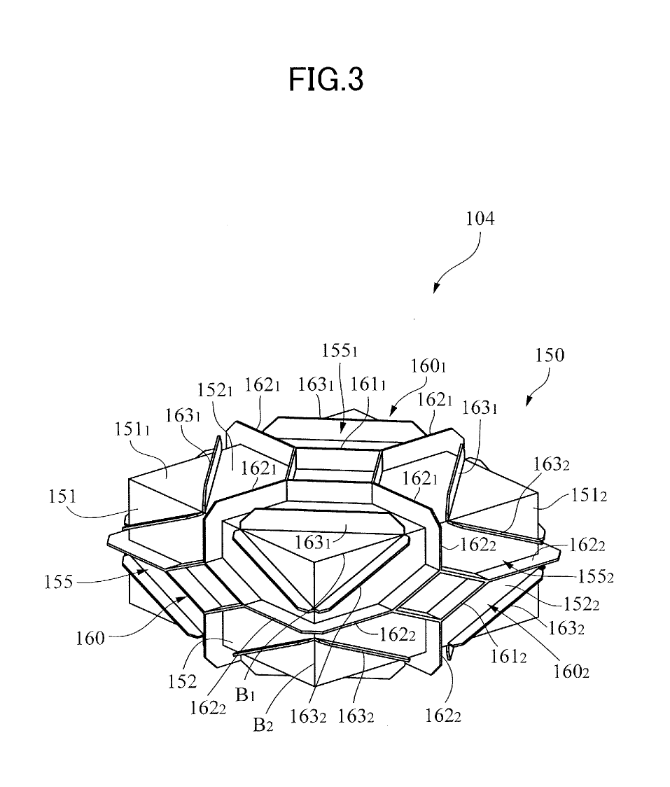

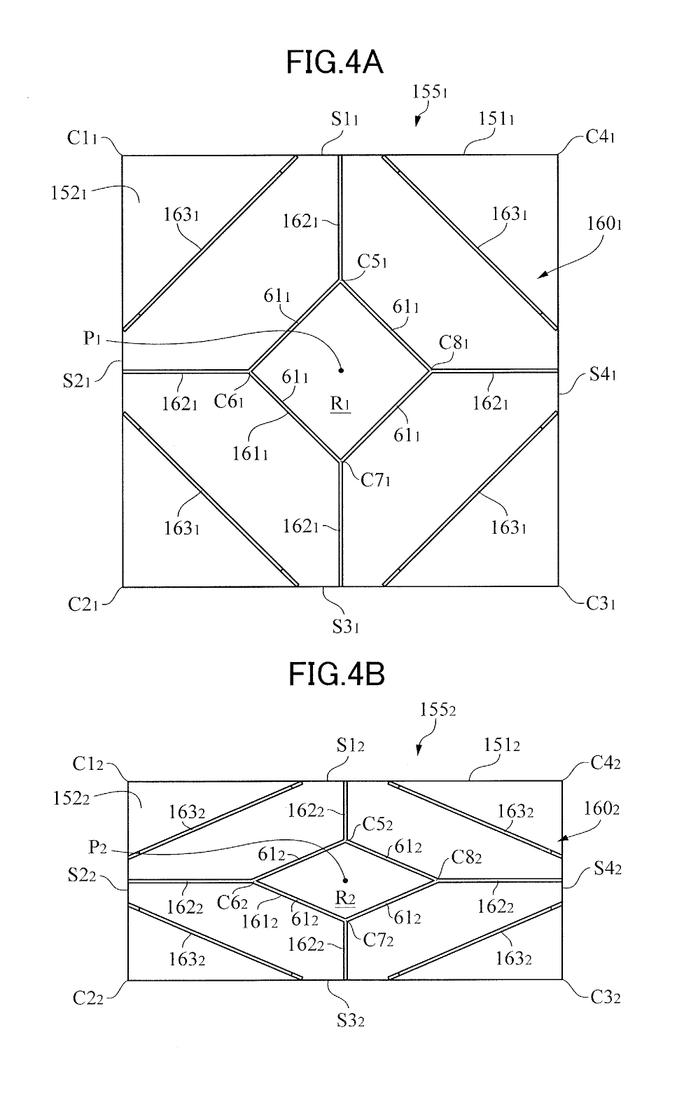

FIG. 3 is a perspective view of a decompression container 104 according to the first exemplary embodiment. FIG. 4A is a plan view of an upper surface portion or a lower surface portion of the decompression container 104 according to the first exemplary embodiment. FIG. 4B is a plan view of a side surface portion of the decompression container 104 according to the first exemplary embodiment.

As illustrated in FIG. 3, the decompression container 104 includes a container body 150. The container body 150 is formed of, for example, metal such as stainless steel. When six outer surfaces of the container body 150 are each regarded as an outer wall, the container body 150 includes six members 155 each constituting the outer wall, and has a substantially rectangular parallelepiped shape formed by joining the members 155 to one another by, for example, welding. Examples of the welding include welding performed without a welding rod. The members 155 each include a plate member 151 and a rib portion 160. The plate member 151 has a flat plate shape, and serves as a substrate portion having a quadrilateral outer surface 152. The rib portion 160 is joined to the outer surface 152 of the plate member 151 by, for example, welding without a welding rod or spot welding. Hereinafter, description will be given by referring to members 155 constituting the upper surface portion and the lower surface portion of the container body 150 as members 155₁, and referring to members 155 constituting side surface portions of the container body 150 as members 155₂.

An outer surface 152₁ of a plate member 151₁ is square, and an outer surface 152₂ of a plate member 151₂ is rectangular. In addition, a plate member 151₁ of the upper surface portion or the lower surface portion of the container body 150 and two plate members 151₂ constituting side surface portions are disposed adjacent to one another so as to be perpendicular to one another. In addition, two plate members 151₂ constituting adjacent side surface portions of the container body 150 are also disposed adjacent to each other so as to be perpendicular to each other.

The rib portion 160 for reinforcement is provided to stand on the outer surface 152 of each of the six plate members 151. Since the plate member 151 is reinforced by the rib portion 160, the thickness of the plate member 151 can be reduced while increasing the strength of the decompression container 104, and thus the weight of the decompression container 104 can be reduced. It suffices as long as the rib portion 160 is provided on at least one of the plurality of plate members 151. A plate member 151 not provided with the rib portion 160 may be, to maintain a high strength, thicker than the plate member 151 provided with the rib portion 160. Therefore, on the more plate members 151 the rib portion 160 is provided, the more weight of the decompression container 104 can be reduced. Hereinafter, a rib portion 160 provided on a plate member 151₁ will be referred to as a rib portion 160₁, and a rib portion 160 provided on a plate member 151₂ will be referred to as a rib portion 160₂.

The rib portion 160₁ on the upper surface portion and the lower surface portion of the container body 150 will be described. The rib portion 160₁ includes a rib 161₁ serving as a first rib, four ribs 162₁ serving as a plurality of second ribs, and four ribs 163₁ serving as a plurality of third ribs.

The rib 161₁ serving as a first rib is a rib disposed on the outer surface 152₁ to surround a center P₁ of the quadrilateral outer surface 152₁ as illustrated in FIG. 4 A. The center P₁ is an intersection point of two diagonals each connecting two opposing vertices of the outer surface 152₁. In the first exemplary embodiment, the rib 161₁ is a rib formed by joining four linear ribs 61₁ into a quadrilateral shape. That is, the rib 161₁ has a quadrilateral shape as viewed in a direction perpendicular to the outer surface 152₁. The rib 161₁ has a closed shape continuous in a circumferential direction so as to secure strength. A region R₁ surrounded by the rib 161₁ is a region inside the rib 161₁. This region R₁ is a region in which no other rib is disposed. Even if another rib is disposed in the region R₁ inside the rib 161₁, the effect of reinforcement of this additionally disposed rib is small. Since no other rib is disposed in the region R₁ in the first exemplary embodiment, the weight of the decompression container 104 can be reduced even more.

A rib 162₁ serving as a second rib is disposed on the outer surface 152₁ so as to be connected to the rib 161₁ and extend toward one of sides S1₁ to S4₁ of the quadrilateral shape of the outer surface 152₁. In the first exemplary embodiment, the four ribs 162₁ extend radially toward the respective sides S1₁ to S4₁. Although each of the ribs 162₁ does not have to reach the corresponding one of the sides S1₁ to S4₁, it is preferable that each of the ribs 162₁ reaches the corresponding one of the sides S1₁ to S4₁. In the first exemplary embodiment, the ribs 162₁ reach the sides S1₁ to S4₁, and thus the effect of reinforcement of the ribs 162₁ is enhanced, the strength of the decompression container 104 is further increased, and deformation of the decompression container 104 can be suppressed more effectively. In the case where the ribs 162₁ do not reach the sides S1₁ to S4₁, it is preferable that the distances from ends of the ribs 162₁ to the sides of the outer surface 152₁ are 100 mm or shorter as viewed in the direction perpendicular to the outer surface 152₁. That is, the ribs 162₁ are disposed so as to extend to positions reaching the sides S1₁ to S4₁ or positions in the vicinity of the sides S1₁ to S4₁, specifically, positions 100 mm or closer from the sides S1₁ to S4₁.

The ribs 162₁ are each a linear rib perpendicular to the corresponding one of the sides S1₁ to S4₁ as viewed in the direction perpendicular to the outer surface 152₁. By disposing the ribs 162₁ to he respectively perpendicular to the sides S1₁ to S4₁, the strength of the decompression container 104 is further increased, and deformation of the decompression container 104 can be suppressed more effectively. That is, the weight of the decompression container 104 can be further reduced.

In addition, the four ribs 162₁ include a pair of ribs 162₁ respectively extending toward two opposing sides S1₁ and S3₁ of the quadrilateral and a pair of ribs 162₁ extending toward two opposing sides S2₁ and S4₁ of the quadrilateral. Deformation of the decompression container 104 can foe effectively suppressed by the pair of ribs 162₁ respectively extending toward the two sides S1₁ and S3₁. Deformation of the decompression container 104 can be also affectively suppressed by the pair of ribs 162₁ respectively extending toward the two sides S1₁ and S4₁. Since the ribs 162₁ extend in four directions toward the four sides S1₁ to S4₁ in the first exemplary embodiment, deformation of the decompression container 104 can be suppressed more effectively. That is, the weight of the decompression container 104 can be further reduced.

In addition, the four ribs 162₁ respectively extend from corners C5₁, C6₁, C7₁, and C8₁ of the polygonal rib 161₁ toward the sides S1₁ to S4₁. Since the ribs 162₁ extend from the corners C5₁, C6₁, C7₁, and C8₁, the effect of reinforcing the plate member 151₁ is increased compared with a case where the ribs 162₁ extend from the middle of the ribs 61₁, and the weight of the decompression container 104 can be further reduced.

The ribs 163₁ serving as third ribs are disposed on the outer surface 152₁ so as to respectively oppose corners C1₁, C2₁, C3₁, and C4₁ of the quadrilateral outer surface 152₁. That is, one or more ribs 163₁ are disposed in correspondence with each of the corners C1₁, C2₁, C3₁, and C4₁. In the first exemplary embodiment, one rib 163₁ is provided for each of the corners C1₁, C2₁, C3₁, and C4₁. That is, four ribs 163₁ are provided in total.

The four ribs 163₁ are disposed on the outer surface 152₁ so as to respectively extend toward pairs of adjacent sides forming the respective corners C1₁, C2₁, C3₁, and C4₁, that is, toward sides S1₁ and S2₁, sides S2₁ and S3₁, sides S3₁ and S4₁, and sides S4₁ and S1₁. Although the ribs 163₁ do not have to reach the sides S1₁ to S4₁, it is preferable that the ribs 163₁ reach the sides S1₁ to S4₁. In the first exemplary embodiment, the ribs 163₁ are each disposed so as to reach two adjacent sides, that is, connect two adjacent sides. In the first exemplary embodiment, since the ribs 163₁ reach the sides S1₁ to S4₁, the affect of reinforcement of the ribs 163₁ is enhanced, the strength of the decompression container 104 is further increased, and deformation of the decompression container 104 can be suppressed more effectively. In the case where the ribs 163₁ do not reach the sides S1₁ to S4₁, it is preferable that distances between ends of the ribs 163₁ and the sides S1₁ to S4₁ of the outer surface 152₁ are 100 mm or shorter as viewed in the direction perpendicular to the outer surface 152₁. That is, the ribs 163₁ are disposed so as to extend to positions reaching the sides S1₁ to S4₁ or positions in the vicinity of the sides S1₁ to S4₁, specifically, positions 100 mm or closer from the sides S1₁ to S4₁.

The ribs 163₁ serving as third ribs are not connected to one another at the sides S1₁ to S4₁. That is, a third rib 163₁ disposed on a quadrilateral outer surface is apart from another third rib 163₁ disposed on the quadrilateral outer surface. Taking the side S1₁ as an example, two ribs 163₁ reach the side S1₁, and the two ribs 163₁ are not connected to each other at the side S1₁. That is, the two ribs 163₁ are not in contact with each other. The same applies to the sides S2₁ to S4₁. A rib 163₁ is a linear rib inclined with respect to both of two adjacent sides forming a corner that the rib 163₁ opposes. Each rib 163₁ is disposed on the outer surface 152₁ in parallel with a rib 61₁ that the rib 163₁ opposes.

Next, the rib portion 160₂ on the side surface portion of the container body 150 will be described. That is, as illustrated in FIG. 4B, the rib portion 160₂ includes a rib 161₂ serving as a first rib, four ribs 162₂ serving as a plurality of second ribs, and four ribs 163₂ serving as a plurality of third ribs similarly to the rib portion 160₁. Although the ribs 161₂, 162₂, and 163₂ of the rib portion 160₂ disposed on a rectangular outer surface 152₂ are respectively provided in the same number as the ribs 161₁, 162₁, and 163₁ of the rib portion 160₁ disposed on the square outer surface 152₁, the ribs 161₂, 162₂, and 163₂ are different from the ribs 161₁, 162₁, and 163₁ in the angle of inclination and so forth.

The rib 161₂ serving as a first rib is disposed on the outer surface 152₂ so as to surround a center P₂ of the quadrilateral outer surface 152₂ similarly to the rib 161₁. A region R₂ inside the rib 161₂ is a region in which no other rib is disposed similarly to the region R₁. A rib 162₂ serving as a second rib is connected to the rib 161₂ similarly to a rib 162₁, and extends radially toward corresponding one of sides S1₂ to S4₂ of the quadrilateral shape of the outer surface 152₂. Specifically, the ribs 162₂ respectively extend from corners C5₂; C6₂, C7₂, and C8₂ of the polygonal rib 161₂ toward the sides S1₂ to S4₂. A rib 163₂ serving as a third rib is disposed so as to be inclined with respect to both of two adjacent sides of the quadrilateral outer surface 152₂ similarly to a rib 163₁.

According to the configurations of the rib portions 160₁ and 160₂ described above, deformation of the decompression container 104 can be suppressed effectively, and thus the weight of the container body 150 can be reduced. That is, the weight of the decompression container 104 can be reduced while maintaining a high strength of the decompression container 104.

In the first exemplary embodiment, with regard to two adjacent members 155₁ and 155₂ respectively constituting the upper surface and a side surface of the container body 150, the four ribs 162₁ of the member 155₁ serving as a first member include a rib 162₁ extending toward a boundary B₁ between the two outer surfaces 152₁ and 152₂. Similarly, the four ribs 162₂ of the member 155₂ serving as a second member include a rib 162₂ extending toward the boundary B₁. The rib 162₁ extending toward the boundary B₁ and the rib 162₂ extending toward the boundary B₁ are connected to and integrated with each other at the boundary B₁.

In addition, with regard to two adjacent members 155₂ constituting two side surfaces of the container body 150, four ribs 162₂ of one member 155₂ serving as a first member include a rib 162₂ extending toward a boundary B₂ between two adjacent outer surfaces 152₂. Similarly, four ribs 162₂ of the other member 155₂ serving as a second member include a rib 162₂ extending toward the boundary B₂. The two ribs 162₂ extending toward the boundary B₂ are connected to and integrated with each other at the boundary B₂.

Meanwhile, a rib 163₁ serving as a third rib and a rib 163₂ serving as a third rib are, although close to or in contact with each other, not connected to or integrated with each other at the boundary B₁ between two adjacent members 155₁ and 155₂. This is because connecting and integrating these ribs cause unnecessary increase of the weight.

As a result of connecting a rib 162₁ and a rib 162₂ to each other and connecting ribs 162₂ to each other as described above, the effect of reinforcement is further enhanced, deformation of the decompression container 104 can be suppressed effectively, and thus the weight of the decompression container 104 can be further reduced.

### Second Exemplary Embodiment

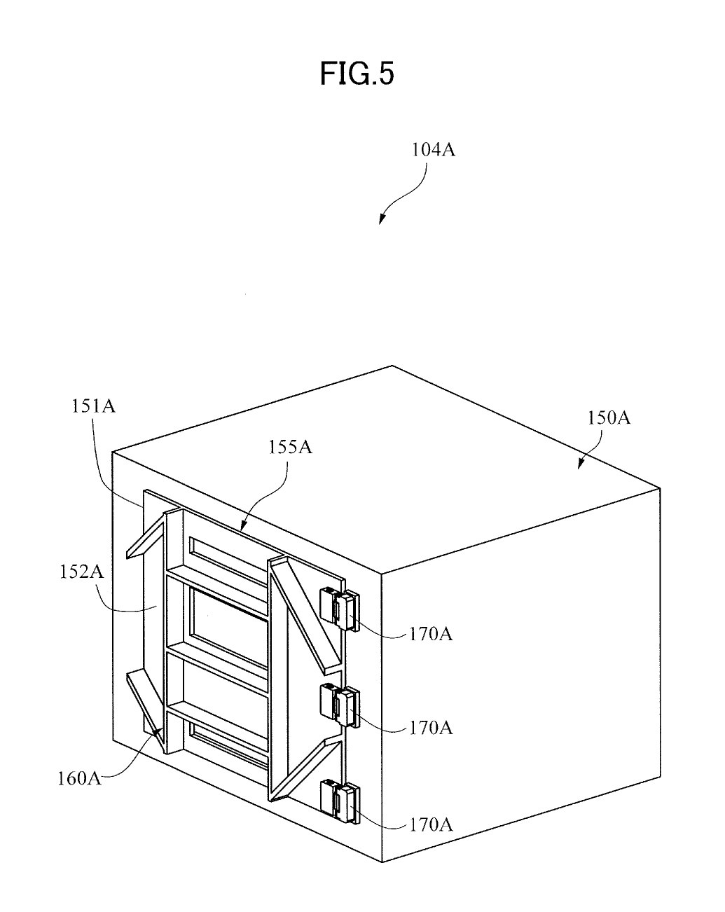

Next, a decompression container according to a second exemplary embodiment will be described. FIG. 5 is a perspective view of the decompression container according to the second exemplary embodiment. In the second exemplary embodiment, as illustrated in FIG. 5, a member constituting a part of one outer wall of a decompression container 104A is a door 155A configured to be opened and closed with respect to a container body 150A. The door 155A is fixed by a plurality of hinges 170A so as to be an openable and closable with respect to the container body 150A.

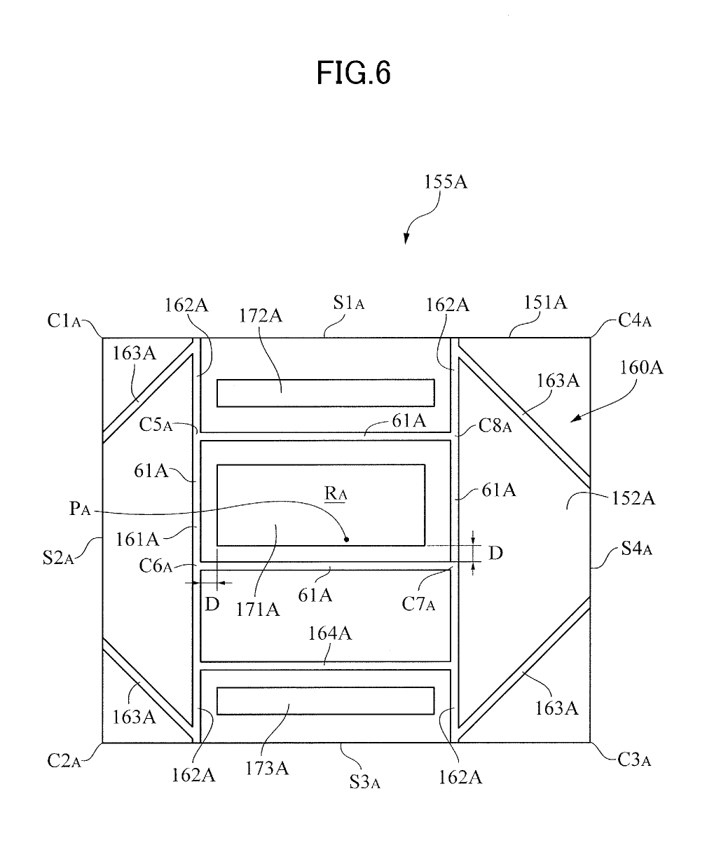

FIG. 6 is a plan view of the door 155A of the decompression container 104A according to the second exemplary embodiment. The door 155A includes a door body 151A and a rib portion 160A. The door body 151A is a base portion having a flat plate shape and including a quadrilateral outer surface 152A. The rib portion 160A is disposed on the outer surface 152A, and includes a rib 161A serving as a first rib, four ribs 162A serving as a plurality of second ribs, and four ribs 163A serving as a plurality of third ribs.

The rib 161A serving as a first rib is a rib disposed on the outer surface 152A to surround a center P_{A} of the quadrilateral outer surface 152A. In the second exemplary embodiment, the rib 161A is a rib formed by joining four linear ribs 61A into a quadrilateral shape. That is, the rib 161A has a quadrilateral shape as viewed in a direction perpendicular to the outer surface 152A. The rib 161A has a closed shape continuous in a circumferential direction so as to secure strength. A region R_{A} surrounded by the rib 161A is a region inside the rib 161A. This region is a region in which no other rib is disposed.

A rib 162A serving as a second rib disposed on the outer surface 152A so as to be connected to the rib 161A and extend toward one of sides S1_{A} to S4_{A} of the quadrilateral shape of the outer surface 152A. In the second exemplary embodiment, two of the four ribs 162A extend toward the side S1_{A}, and the other two of the four ribs 162A extend toward the side S3_{A}. Although each of the ribs 162A does not have to reach the corresponding one of the aides S1_{A} and S3_{A}, it is preferable that each of the ribs 162A reaches the corresponding one of the sides S1_{A} and S3_{A}. In the second exemplary embodiment, the ribs 162A reach the sides S1_{A} and S3_{A}, and thus the effect of reinforcement of the ribs 162A is enhanced, the strength of the decompression container 104A is further increased, and deformation of the decompression container 104A can be suppressed more effectively. In the case where the ribs 162A do not reach the sides S1_{A} and S3_{A}, it is preferable that the distances from ends of the ribs 162A to the sides of the outer surface 152A are 100 mm or shorter as viewed in the direction perpendicular to the outer surface 152A. That is, the ribs 162A are disposed so as to extend to positions reaching the sides S1_{A} and S3_{A} or positions in the vicinity of the sides S1_{A} and S3_{A}, specifically, positions 100 mm or closer from the sides S1_{A} and S3_{A}.

The ribs 162A are each a linear rib perpendicular to the corresponding one of the sides S1_{A} and S3_{A} as viewed in the direction perpendicular to the outer surface 152A. By disposing the ribs 162A to be perpendicular to the sides S1_{A} and S3_{A}, the strength of the decompression container 104A is further increased, and deformation of the decompression container 104A can be suppressed more effectively.

In addition, the four ribs 162A include two pairs of ribs 162A respectively extending toward the two opposing sides S1_{A} and S3_{A} of the quadrilateral shape of the outer surface 152A. The two pairs of ribs 162A effectively prevent deformation of the decompression container 104A. Since hinges, a pull, and so forth are attached to the left side and right side of the door body 151A, the ribs 162A are configured to extend only in the vertical direction.

In addition, the four ribs 162A respectively extend from corners C5_{A}, C6_{A}, C7_{A}, and C8_{A} of the polygonal rib 161A toward the sides S1_{A} and S3_{A}. Since the ribs 162A extend from the corners C5_{A}, C6_{A}, C7_{A}, and C8_{A}, the effect of reinforcing the door body 151A is increased compared with a case where the ribs 162A extend from the middle of the ribs 61A, and the weight of the decompression container 104A can be further reduced.

The ribs 163A serving as third ribs are disposed on the outer surface 152A so as to respectively oppose corners C1_{A}, C2_{A}, C3_{A}, and C4_{A} of the quadrilateral outer surface 152A. That is, one or more ribs 163A are disposed in correspondence with each of the corners C1_{A}, C2_{A}, C3_{A}, and C4_{A}. In the second exemplary embodiment, one rib 163A is provided for each of the corners C1_{A}, C2_{A}, C3_{A}, and C4_{A}. That is, four ribs 163A are provided in total.

The four ribs 163_{A} are disposed on the outer surface 152A so as to respectively extend toward pairs of adjacent sides forming the respective corners C1_{A}, C2_{A}, C3_{A}, and C4_{A}, that is, toward sides S1_{A} and S2_{A}, sides S2_{A} and S3_{A}, sides S3_{A} and S4_{A}, and sides S4_{A} and S1_{A}.

The ribs 163A serving as third ribs are not connected to one another at the respective sides S1_{A} to S4_{A}. Further, one end of each of the ribs 163A does not reach the side S1_{A} or S3_{A} and is connected to the corresponding one of the ribs 162A, and the other end reaches the side S2_{A} or S4_{A}. That is, a third rib 163A disposed on the quadrilateral outer surface 152A is apart from another third rib 163A disposed on the quadrilateral outer surface 152A on a side of the quadrilateral outer surface 152A.

Taking the side S1_{A} as an example, two ribs 163A extending toward the side S1_{A} do not reach the side S1_{A}, and the two ribs 163A are not connected to each other at the side S1_{A}. That is, the two ribs 163A are not in contact with each other. A rib 163A is a linear rib inclined with respect to both of the corresponding pair of adjacent sides of the quadrilateral shape of the outer surface 152A.

A window 171A is provided in the region R_{A}. The window 171A is a viewing port for an operator to visually observe the inside of the decompression container 104A, and, for example, a glass type material is mainly used. Glass has lower rigidity and lower strength than stainless steel, and thus is easily deformed or broken. In the second exemplary embodiment, the rib 161A is disposed so as to surround the window 171A, and thus deformation of the window 171A can be suppressed. To be noted, an opening for connection to another decompression container may be provided in the region R_{A} instead of the window 171A.

Distance D between the rib 161A and the window 171A, more specifically, distance D from an inner edge of the rib 161A to an edge of the window 171A is preferably 100 mm or shorter. As a result of setting the distance D to 100 mm or shorter, the rib 161A and the window 171A are close to each other, and deformation of the window 171A can be suppressed effectively. Although the lower limit value of the distance D is not particularly limited, the lower limit value is preferably 10 mm from the viewpoint of securing a clearance between the rib 161A and the window 171A.

In addition, in the second exemplary embodiment, the rib portion 160A includes a rib 164A connecting a pair of ribs 162A parallel to each other. In addition, a window 172A is disposed on the upper side of the rib 161A and a window 173A is disposed on the lower side of the rib 164A.

Deformation of the decompression container 104A can be suppressed effectively according to the configuration of the rib portion 160A described above, and thus the weight of the door 155A can be reduced. That is, the weight of the decompression container 104A can be reduced while maintaining high strength of the decompression container 104A.

### Modification Embodiment

In a vapor deposition apparatus used for producing an organic electroluminescence device, film formation is performed after performing alignment of a substrate and a mask. The substrate and the mask need to be aligned with a precision of the order of micrometers, and thus it takes a long time to perform the alignment. In particular, in the case where the size of the substrate is larger than a substrate of the so-called fourth generation, that is, 680 mm×880 mm, vibration or distortion occurs in the substrate, and the time required for the alignment increase. Therefore, it can be considered that the rate of operation of the apparatus is improved by using a decompression container having a volume twice as large as a volume required for forming a film on a substrate of a corresponding size and, while performing the alignment in a half of space in a decompression container, performing film formation in the other half of the space in the decompression container. However, in the case of such a vapor deposition apparatus, the size and weight of the decompression container further increases.

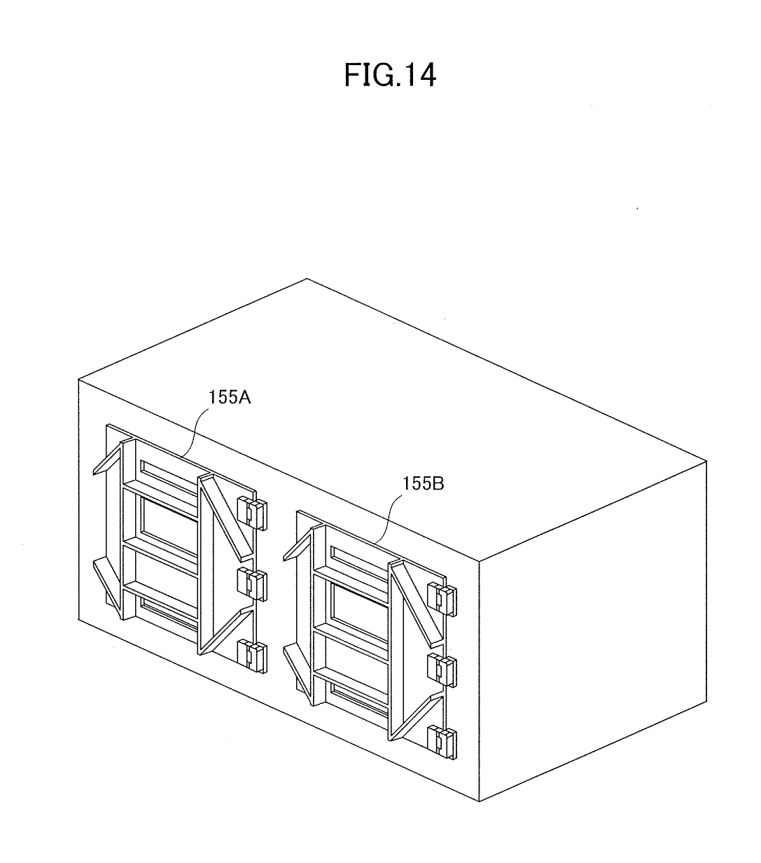

Therefore, in the case of such a large decompression container, it is preferable that, as illustrated in FIG. 14, two doors 155A and 155B each having a structure similar to the door 155A illustrated in FIG. 5 are provided instead of providing one large door. The number of doors is not limited to two, and may be three or more depending on the size of the decompression container. In addition, a plurality of doors having different sizes may be provided.

According to such a configuration, the size of an opening provided in the decompression container can be reduced, thus the weight of the doors can be reduced while maintaining the strength of the decompression container, and the weight of the decompression container can be reduced while maintaining high strength of the decompression container as a whole.

### EXAMPLES

### Example 1

Simulation was performed for the decompression container 104 described in the first exemplary embodiment. The dimensions of the substrate W were set to a width of 925 mm, a length of 1500 mm, and a thickness of 0.4 mm, and the container body 150 excluding the rib portion 160 was configured as a rectangular parallelepiped having a width of 4000 mm, a length of 4000 mm, and a height of 2000 mm. SUS304 was used as the material of the container body 150, and the thickness of the plate member 151 was set to 30 mm. The heights of the ribs were determined in accordance with the upper limit of the size of the external shape of the apparatus, and the height limit was set to 300 mm. As performance of the decompression container 104, the amount of maximum displacement of each surface in a state where the inside of the container was in vacuum and the outside of the container was in normal pressure, that is, in a state where a pressure of 0.1 MPa was applied to each surface of the decompression container 104 was obtained.

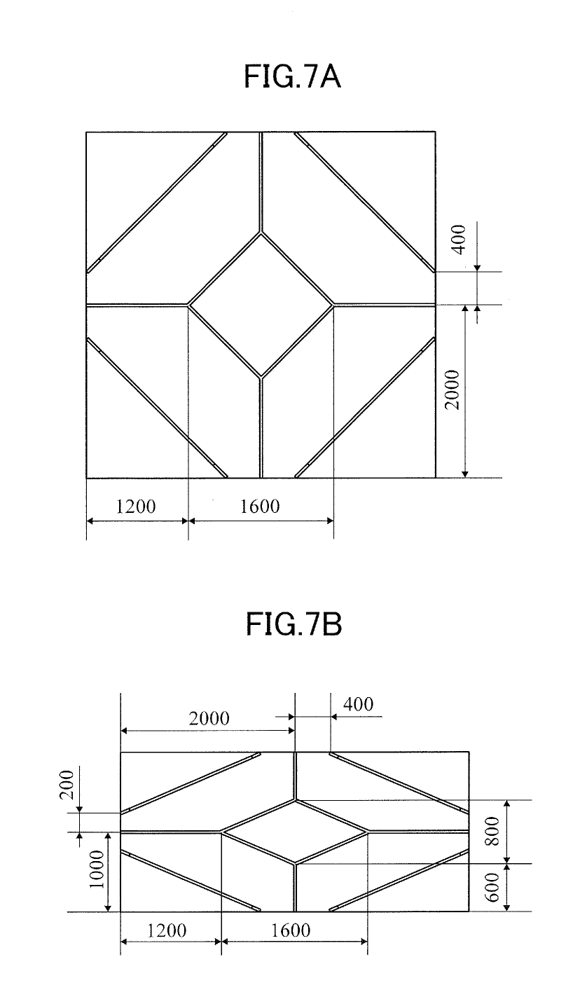

In addition, both ends of each third rib were chamfered by 100 mm, and connecting portions between second ribs were each chamfered by 200 mm. FIG. 7A is an explanatory diagram illustrating dimensions of the members constituting the upper surface portion and the lower surface portion of the decompression container 104 of Example 1. FIG. 7B is an explanatory diagram illustrating dimensions of the members constituting the side surface portions of the decompression container 104 of Example 1. The unit of the dimensions is mm. Simulation was performed by setting the dissensions of each rib as illustrated in FIGS. 7A and 7B. To be noted, since the rib structure is symmetrical in the vertical direction and in the horizontal direction, the illustration of the dimensions is limited to part of the ribs.

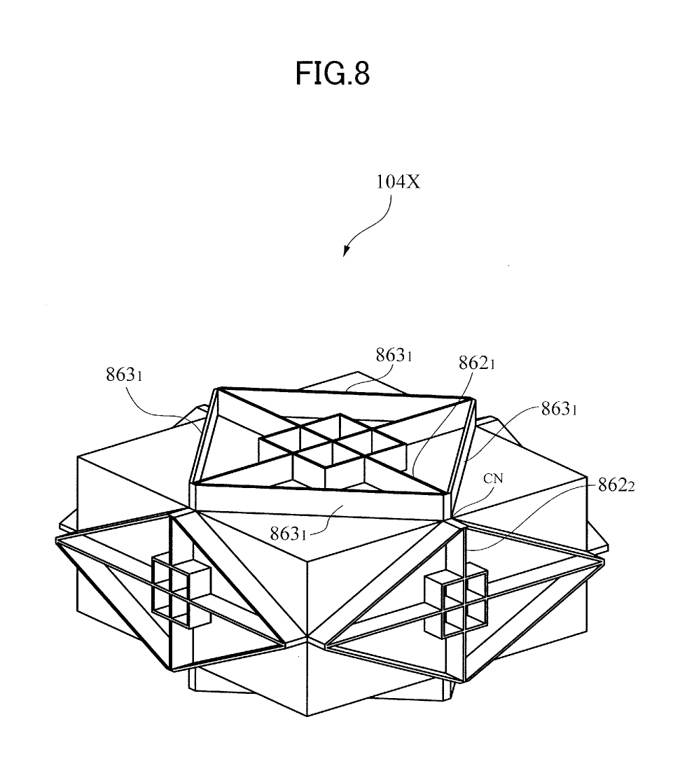

Here, simulation was also performed for a decompression container of Comparative Example 1. FIG. 8 is a perspective view of a decompression container 104X of Comparative Example 1. The decompression container 104X of Comparative Example 1 illustrated in FIG. 8 has a configuration in which the rib structure disclosed in Japanese Patent Laid-Open No. 2010-243015 is provided on all six surfaces of the container body. The thicknesses of the ribs were uniformly set to 30 mm, and the heights of the ribs were uniformly set to 300 mm.

As illustrated in FIG. 8, although ribs 862₁ disposed on the upper surface of the decompression container 104X of Comparative Example 1 are close to or in contact with ribs 862₂ disposed on side surfaces of the container in the vicinity of points CN, the ribs 862₁ are not connected to or integrated with the ribs 862₂. In addition, ribs 863₁ disposed so as to oppose corner portions of quadrilateral outer surfaces of the container are connected to and integrated with the other ribs 863₁ disposed on the quadrilateral outer surfaces on sides of the quadrilateral outer surfaces.

The simulation was performed by a finite element method. The finite element method is a technique widely used for performance evaluation of structures and estimation of displacement and stress. The amounts of maximum displacement when a pressure of 0.1 MPa is applied to all the surfaces of the bodies of the decompression containers 104 and 104X perpendicularly in a state where four corners of each lower surface portion of the decompression containers 104 and 104X are fixed with respect to six-axes directions were calculated by using the finite element method.

Specifications of finite element models of Example 1 and Comparative Example 1 are shown in Table 1 below.

TABLE 1

| | |
|---|---|
| TYPE OF | QUADRILATERAL OR TRIANGULAR PRIMARY |
| ELEMENT | PLANAR ELEMENT |
| | STANDARD ELEMENT LENGTH: 80 mm |
| MATERIAL | YOUNG'S MODULUS: 1930000 MPa |
| | (LINEAR MATERIAL) |
| | POISSON'S RATIO: 0.3 |

Weights [t] and amounts of maximum displacement [mm] obtained by the simulation are shown in Table 2 below. The center point of the lower surface portion was the position with the maximum displacement in both of the model of Example 1 and the model of Comparative Example 1.

TABLE 2

| | WEIGHT | AMOUNT OF MAXIMUM |
|---|---|---|
| | [t] | DISPLACEMENT [mm] |
| EXAMPLE 1 | 19.8 | 2.70 |
| COMPARATIVE EXAMPLE 1 | 22.0 | 2.77 |

As shown in Table 2, although the amounts of maximum displacement of the model of Example 1 and the model of Comparative Example 1 were similar, the weight of the model of Example 1 was smaller. As a result of this, it was revealed that the weight of the decompression container 104 could be reduced by the structure of the rib portion 160 of Example 1.

### Examples 2 and 3

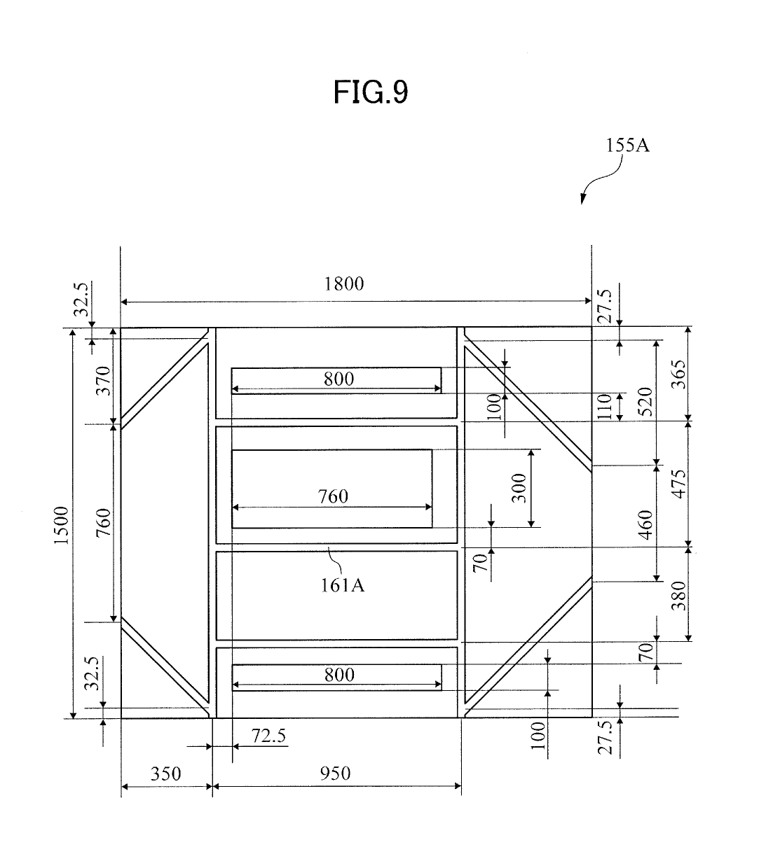

Simulation was performed for the decompression container 104A described in the second exemplary embodiment. FIG. 9 is an explanatory diagram of the dimensions of the door 155A of Examples 2 and 3. In FIG. 9, dimensions are illustrated by using centers of the ribs in the thickness directions thereof as standards. In addition, the thicknesses of the ribs of the door 155A were all set to 30 mm. In Examples 2 and 3, the space around the windows was set to 50 mm or larger, the clearance between a glass edge and an inner edge of the rib 161A was set to 10 mm or larger, and the distance between the inner edge of the rib 161A and the edge of the window was set to 60 mm or longer. In Example 2, the thickness of the plate member of the door 155A was set to 30 mm. In Example 3, the thickness of the plate member of the door 155A was set to 25 mm.

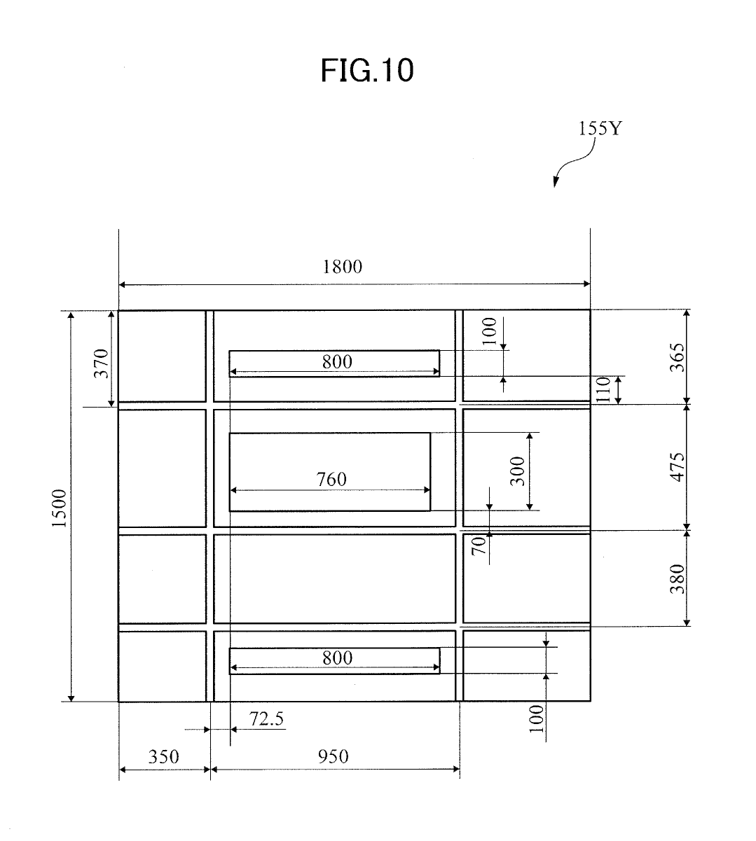

Here, simulation was also performed for a decompression container of Comparative Example 2. FIG. 10 is an explanatory diagram of the dimensions of the door 155Y of the decompression container of Comparative Example 2. The thickness of the plate member of the door 155Y was set to 30 mm.

Since the rib structure disclosed in Japanese Patent Laid-Open No. 2010-243015 cannot be applied to Examples 2 or 3 in which a window is provided in the center, a simple lattice-shaped rib structure as illustrated in FIG. 10 was used for the model of Comparative Example 2. To be noted, since this simulation was performed to compare the rib structures of doors, common portions such as the container bodies and the window members were omitted in the models of Examples 2 and 3 and Comparative Example 2. That is, models of only doors and rib portions were used for the simulation.

The amounts of maximum displacement when a pressure of 0.1 MPa is applied to the entire surfaces of the doors perpendicularly in a state where outer circumferential ends of the back surfaces of the doors were fixed were calculated by using the finite element method. Specifications of finite element models of Examples 2 and 3 and Comparative Example 2 are shown in Table 3 below.

TABLE 3

| | |
|---|---|
| TYPE OF | QUADRILATERAL OR TRIANGULAR PRIMARY |
| ELEMENT | PLANAR ELEMENT |
| | STANDARD ELEMENT LENGTH: 60 mm |
| MATERIAL | YOUNG'S MODULUS: 1930000 MPa |
| | (LINEAR MATERIAL) |
| | POISSON'S RATIO: 0.3 |

Weights [t] and amounts of maximum displacement [mm] obtained by the simulation are shown in Table 4 below.

TABLE 4

| | | AMOUNT OF | THICKNESS |
|---|---|---|---|
| | WEIGHT | MAXIMUM | OF |
| | [kg] | DISPLACEMENT [mm] | DOOR [mm] |
| EXAMPLE 2 | 790 | 0.7 | 30 |
| EXAMPLE 3 | 702 | 0.8 | 25 |
| COMPARATIVE | 794 | 0.8 | 30 |
| EXAMPLE 2 | | | |

In the model of Example 2, the amount of deformation was smaller than in the model of Comparative Example 2, and the weight was also smaller than in the model of Comparative Example 2. In addition, in the model of Example 3, although the amount of deformation was the same as in the model of Comparative Example 2, the weight was smaller than in the model of Comparative Example 2 by 92 kg. That is, by applying the rib structure of Example 2 or 3 to a door of a decompression container, the weight of the decompression container can be reduced while maintaining the rigidity of the decompression container.

### Modification Embodiment

The present invention is not limited to the exemplary embodiments described above, and can be modified within the technical concept of the present invention.

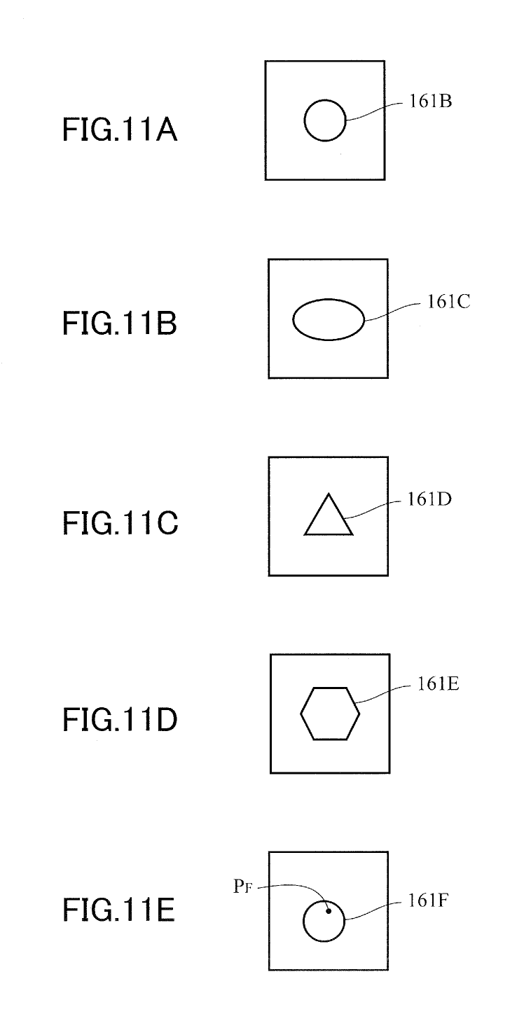

FIGS. 11A to 11E are explanatory diagrams illustrating modification examples of the first rib. In the exemplary embodiments described above, a case where the first rib is quadrilateral as viewed in a direction perpendicular to the enter surface has been described. However, the shape of the first rib is not limited to this. The first rib may be in different shapes as long as the first rib surrounds the center of the outer surface of the decompression container, and various shapes can be employed. For example, the first rib may be circular as a rib 161B illustrated in FIG. 11A, or elliptical as a rib 161C illustrated in FIG. 11E. In addition, the first rib may have a polygonal shape different from quadrilateral. For example, the first rib may be triangular as a rib 161D illustrated in FIG. 11C, or hexagonal as a rib 161E illustrated in FIG. 11D. In addition, the center of the first rib does not have to coincide with the center of the outer surface as long as the first rib surround the center of the outer surface as a rib 161F surrounding a center PF illustrated in FIG. 11E.

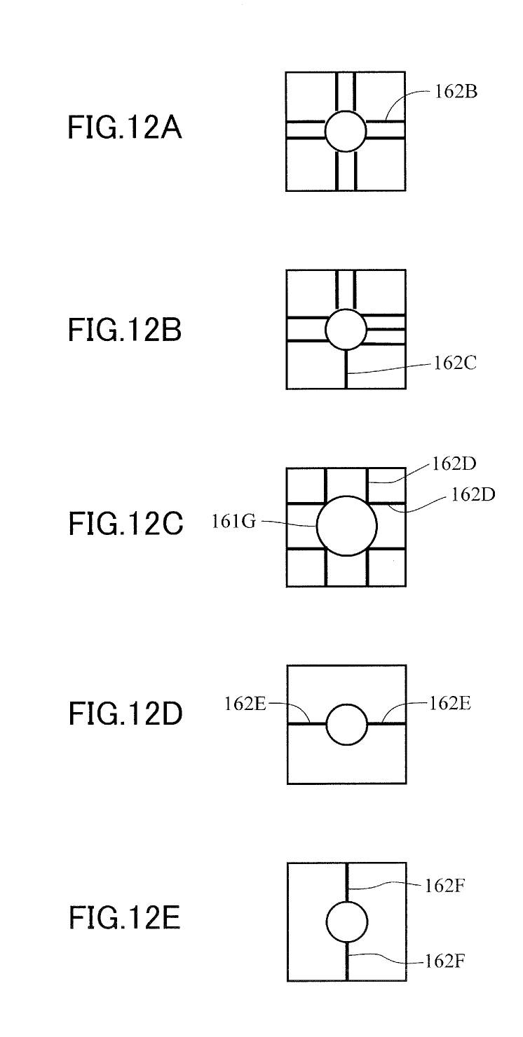

FIGS. 12A to 12E are explanatory diagrams illustrating modification examples of the second ribs. Although a case where the number of the second ribs is four has been described in the exemplary embodiments described above, the number of the second ribs is not limited to this. For example, more than four second ribs may be provided as ribs 162B illustrated in FIG. 12A. In addition, the number of second ribs extending toward respective sides may be different as second ribs 162C illustrated in FIG. 12B. In addition, two second ribs may extend in different directions from the same position on a first rib as second ribs 162D extending from the same position on a first rib 161G illustrated in FIG. 12C. In addition, it is preferable that the plurality of second ribs included in the rib portion include a pair of ribs extending toward two opposing sides of the outer surface. That is, the second ribs of the rib portion may be a pair of ribs extending toward left and right sides as ribs 162E illustrated in FIG. 12D, or may be a pair of ribs extending toward upper and lower sides as ribs 162F illustrated in FIG. 12E.

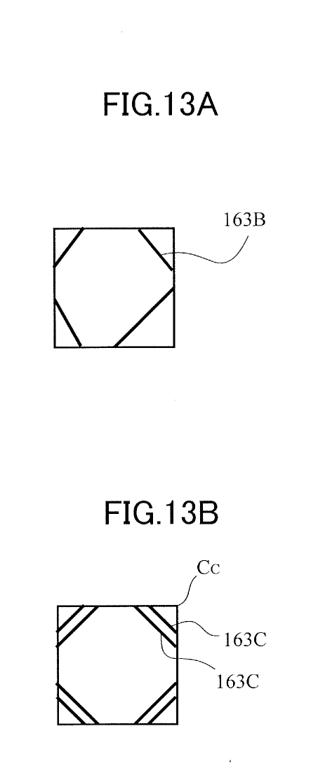

FIGS. 13A and 13B are explanatory diagrams illustrating modification examples of the third ribs. In the exemplary embodiments described above, a case where four third ribs are symmetrically arranged has been described. However, four third ribs may be asymmetrically arranged as ribs 163B illustrated in FIG. 13A. That is, the length of each third rib may be different. In addition, the number of the third ribs is not limited as long as one or more third ribs are disposed in correspondence with each corner of the outer surface. For example, two third ribs may be disposed in correspondence with one corner as two ribs 163C disposed in correspondence with a corner C_{c} illustrated in FIG. 13B.

In addition, although a case where the decompression container 104 or 104A of the processing apparatus 200 includes the rib portion 160 or 160A has been described, the configuration is not limited to this. For example, the decompression containers 101 to 103 and 105 to 110 may include the rib portion 160 or 160A.

In addition, each edge of the plate member may be chamfered. In this case, the second ribs or the third ribs may be disposed only on flat surfaces avoiding chamfered portions. In the case of disposing the second ribs or the third ribs only on the flat surfaces, the ribs have simple shapes and thus an operation of connecting the ribs to the flat surfaces such as welding can be performed easily. In addition, in the case where the second ribs or the third ribs extend to the chamfered portions, the strength increases; and thus the weight of the decompression container can be reduced by a corresponding amount.

In addition, although a case where the rib portion is disposed on the outer surface of a plate member has been described in the exemplary embodiments described above, the rib portion may be disposed on the inner surface.

In addition, although rib portions are disposed on all the outer surfaces of the decompression container, that is, on all of the upper surface, lower surface, and four side surfaces, in the exemplary embodiment, illustrated in FIG. 3, the rib portions do not have to be provided on all the outer surfaces. For example, in the case of a decompression container to be connected to another decompression container such as the decompression container 104, 105, or 106 of the processing system 200 illustrated in FIG. 1, ribs may not be provided on a connecting surface.

In addition, the ribs illustrated in FIG. 4 may be provided on a certain surface of the decompression container and the door provided with ribs illustrated in FIG. 5 or FIG. 14 may be provided on another surface.

In addition, the door provided with ribs illustrated in FIG. 5 or FIG. 14 may be a door for delivering a workpiece into the decompression container or taking out a workpiece from the decompression container in a processing system that processes a workpiece. For example, the door may be a door for delivering and taking out a substrate serving as a raw material into and from decompression container of a film forming apparatus or the like in a production system of a flat panel display.

In addition, the door provided with ribs illustrated in FIG. 5 or FIG. 14 may be a door for maintenance checkup of a processing portion in a decompression container in a processing system that processes a workpiece. For example, in a production system of a flat panel display, the door desirably has a size of 50 cm×50 cm or larger such that a person or a maintenance tool can pass therethrough to get in or out of the decompression container, and desirably has a size of 200 cm×200 cm or smaller to suppress increase of weight.

### Other Embodiments

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No.2017-009001, filed Jan. 20, 2017, which is hereby incorporated by reference herein in its entirety.

What is claimed is:

1. A decompression container comprising;
an outer wall comprising a first member, the first member comprising a first base portion and a first rib portion, the first base portion comprising a first surface having a quadrilateral shape, the first rib portion being disposed on the first surface,
wherein the first rib portion comprises:
a first rib surrounding a center of the first surface;
a plurality of second ribs connected to the first rib and extending toward sides of the quadrilateral shape of the first surface; and
a plurality of third ribs that are respectively disposed to oppose respective corners of the quadrilateral shape of the first surface, extend toward respective pairs of sides forming the respective corners of the quadrilateral shape of the first surface, and are apart from one another.

2. The decompression container according to claim 1, wherein the plurality of second ribs comprise a pair of rib respectively extending toward two opposing sides of the quadrilateral shape of the first surface.

3. The decompression container according to claim 1,
wherein the first rib has a polygonal shape as viewed in a direction perpendicular to the first surface, and
wherein the plurality of second ribs respectively extend from corners of the first rib toward the sides of the quadrilateral shape of the first surface.

4. The decompression container according to claim 1, wherein the plurality of second ribs are linear ribs respectively perpendicular to the sides of the quadrilateral shape of the first surface.

5. The decompression container according to claim 1, wherein the plurality of third ribs are linear ribs inclined with respect to both of the respective pairs of sides forming the respective corners of the quadrilateral shape of the first surface.

6. The decompression container according to claim 1, wherein no rib is provided in a region inside the first rib.

7. The decompression container according to claim 1, wherein a window is provided in a region inside the first rib.

8. The decompression container according to claim 7, wherein a distance between the first rib and the window is 100 mm or shorter.

9. The decompression container according to claim 1,
wherein the decompression container comprises a second member adjacent to the first member and comprising a second base portion and a second rib portion, the second base portion comprising a second surface having a quadrilateral shape, the second rib portion being disposed on the second surface
wherein the second rib portion comprises:
a fourth rib surrounding a center of the second surface;
a plurality of fifth ribs connected to the fourth rib and extending toward sides of the quadrilateral shape of the second surface; and
a plurality of sixth ribs that are respectively disposed to oppose respective corners of the quadrilateral shape of the second surface, extend toward respective pairs of sides forming the respective corners of the quadrilateral shape of the second surface, and are apart from one another, and
wherein a rib comprised in the plurality of second ribs of the first member and extending toward a boundary between the first surface of the first member and the second surface of the second member is connected to, at the boundary, a rib comprised in the plurality of fifth ribs of the second member and extending toward the boundary.

10. The decompression container according to claim 1, wherein the first member is a door that is openable, closable, and provided as a part of the outer wall of the decompression container.

11. The decompression container according to claim 1,
wherein the first member is a door that is openable, closable, and provided as a part of the outer wall of the decompression container, and
wherein the first member is one of a plurality of first members formed on the outer wall.

12. A processing apparatus comprising;
the decompression container according to claim 1; and
a processing portion disposed in the decompression container and configured to perform processing on a workpiece delivered into the decompression container.

13. A processing system comprising:
a plurality of processing apparatuses according to claim 12; and
a decompression container that interconnects a plurality of the decompression containers comprised in the plurality of processing apparatuses and serves as a conveyance path for the workpiece.

14. The processing system according to claim 13, wherein a plurality of the processing portions comprised in the plurality of processing apparatuses comprise a film forming apparatus for forming a film of a material of a flat panel display.

15. A method of producing a flat panel display, the method comprising:
disposing a substrate inside a decompression container comprising an outer wall, the outer wall comprising a member, the member comprising a base portion and a rib portion, the base portion comprising a surface having a quadrilateral shape, the rib portion being disposed on the surface, the rib portion comprising a first rib, a plurality of second ribs, and a plurality of third ribs, the first rib surrounding a center of the surface, the plurality of second ribs being connected to the first rib and extending toward sides of the quadrilateral shape of the surface, the plurality of third ribs being respectively disposed to oppose respective corners of the quadrilateral shape of the surface, extending toward, respective pairs of sides forming the respective corners of the quadrilateral shape of the surface, and being apart from one another;
forming a film of a material of the flat panel display on the substrate in the decompression container; and
taking out the substrate from the decompression container.
